(19) United States
(12) Patent Application Publication
(10) Pub. No.: US 2019/0258457 A1
(43) Pub. Date: Aug. 22, 2019

(54) RANDOM NUMBER GENERATOR AND INTEGRATED DEVICE

(71) Applicant: TDK CORPORATION, Tokyo (JP)

(72) Inventors: Jiro YOSHINARI, Tokyo (JP); Tatsuo SHIBATA, Tokyo (JP)

(73) Assignee: TDK CORPORATION, Tokyo (JP)

(21) Appl. No.: 16/224,899

(22) Filed: Dec. 19, 2018

(30) Foreign Application Priority Data
Feb. 20, 2018 (JP) 2018-027962

(51) Int. Cl. G06F 7/58; H01L 43/02; H01L 43/10

(52) U.S. Cl. CPC G06F 7/588; H01L 43/10; H01L 43/02

(57) ABSTRACT

A random number generator includes a random number generation unit having a first ferromagnetic layer and a nonmagnetic insulating layer laminated on one surface of the first ferromagnetic layer, a voltage application unit which is connected in the lamination direction of the first ferromagnetic layer and the insulating layer and is configured to apply a voltage in the lamination direction of the first ferromagnetic layer and the insulating layer, and a control unit which is connected to the voltage application unit and is configured to determine a time for which a voltage is applied to the first ferromagnetic layer depending on the direction of magnetization of the first ferromagnetic layer precessing by applying the voltage.

### CROSS-REFERENCE TO RELATED APPLICATION

Priority is claimed on Japanese Patent Application No. 2018-027962, filed Feb. 20, 2018, the content of which is incorporated herein by reference.

### BACKGROUND OF THE INVENTION

### Field of the Invention

The present invention relates to a random number generator and an integrated device.

### Description of Related Art

Random numbers include a pseudo-random number and a natural random number. Pseudo-random numbers are obtained using a calculator according to a predetermined program. Pseudo-random numbers have a problem that the same result is output when the same initial value is input to a program and a problem that random numbers have a specific periodicity on the basis of the number of registers of a calculator. On the other hand, natural random numbers are obtained from probabilistic events occurring in the natural world and they are definitely random.

A method using noise in a tunnel junction (the sum of thermal noise and shot noise) in Japanese Unexamined Patent Application, First Publication No. 2003-108364, a method of amplifying thermal noise according to single electron transistor effect in Japanese Unexamined Patent Application, First Publication No. 2004-30071, a method of amplifying thermal noise according to a negative resistance element in Japanese Unexamined Patent Application, First Publication No. 2005-18500, a method using fluctuation of a magnetization free layer according to an external field in a magnetoresistance effect element in Japanese Unexamined Patent Application, First Publication No. 2008-310403, a method using trapping and discharging of electrons in a very thin film silicon-on-insulator (SOI) transistor in K. Uchida et al., J. Appl. Phys, Vol. 90, No. 7, (2001), pp 3551 and the like are known as means for obtaining natural random numbers.

### SUMMARY OF THE INVENTION

However, the random number generators disclosed in Japanese Unexamined Patent Application, First Publication No. 2003-108364, in Japanese Unexamined Patent Application, First Publication No. 2004-30071, and in Japanese Unexamined Patent Application, First Publication No. 2005-18500 require an amplification circuit for amplifying noise and a threshold value circuit for binarizing information and thus are large in size. In addition, the random number generator disclosed in K. Uchida et al., J. Appl. Phys, Vol. 90, No. 7, (2001), pp 3551 has a random number generation speed of 100 kbit/second and thus there is difficulty in such an operation speed being fulfilled.

In addition, the random number generator disclosed in Japanese Unexamined Patent Application, First Publication No. 2008-310403 generates random numbers using a spin transfer torque (STT) generated by flowing current in a lamination direction of magnetoresistance effect elements. However, this random number generator has small tolerances in current and magnetic field applied to obtain random numbers and is easily affected by external factors.

An object of the present invention devised in view of the aforementioned circumstances is to provide a random number generator capable of generating natural random numbers using a rotation direction difference of magnetization after a voltage is applied.

It has been discovered that, after a voltage is applied to a ferromagnetic substance by a voltage application unit, a random number can be generated by stopping the applied voltage.

That is, the following means are employed in order to solve the above-described problems.

(1) A random number generator according to a first aspect includes: a random number generation unit having a first ferromagnetic layer and a nonmagnetic insulating layer laminated on one surface of the first ferromagnetic layer; a voltage application unit which is connected in the lamination direction of the first ferromagnetic layer and the insulating layer and is configured to apply a voltage in the lamination direction of the first ferromagnetic layer and the insulating layer; and a control unit which is connected to the voltage application unit and is configured to determine a time for which a voltage is applied to the first ferromagnetic layer depending on the direction of magnetization of the first ferromagnetic layer precessing by applying the voltage.

(2) The control unit of the random number generator according to the aforementioned aspect may be configured to control a voltage application time t such that the voltage application time satisfies the following equation (1).

$$0.5 - 0.0033 \leq {A}_{0} + {A}_{1} cos ( \frac{2 π ( t - {t}_{1} )}{{τ}_{1}} ) {e}^{\frac{t - {t}_{0}}{{τ}_{0}}} \leq 0.5 + 0.0033 \qquad ( 1 )$$

Here, in equation (1), A₀ is a value of 0.5; A₁, t₀ and t₁ are parameters obtained from a fitting curve when the random number generator is measured; τ₀ is a relaxation time in which precession of the magnetization of the first ferromagnetic layer is disturbed by heat; and τ₁ is a time necessary for a single cycle of the precession of the magnetization of the first ferromagnetic layer.

(3) In the random number generator according to the aforementioned aspect, the thickness of the insulating layer may be 2 nm or more.

(4) The random number generator according to the aforementioned aspect may further include a magnetic field application unit which is disposed at a position at which the magnetic field application unit can apply an external magnetic field to the first ferromagnetic layer and is configured to apply a magnetic field in a direction perpendicular to an axis of easy magnetization of the first ferromagnetic layer.

(5) The random number generator according to the aforementioned aspect may further include a second voltage application unit which is connected in an in-plane direction of the first ferromagnetic layer and is configured to apply a voltage in the in-plane direction of the first ferromagnetic layer.

(6) The random number generator according to the aforementioned aspect may further include a second ferromagnetic layer provided on a surface of the insulating layer opposite to the first ferromagnetic layer.

(7) The random number generator according to the aforementioned aspect may further include: a current application unit which is connected in the in-plane direction of the first ferromagnetic layer and is configured to flow current in a first direction of the in-plane direction of the first ferromagnetic layer; and a voltmeter which is configured to measure a potential difference in a second direction perpendicular to the first direction.

(8) The random number generator according to the aforementioned aspect may further include a magnetic shield provided at positions which the first ferromagnetic layer is interposed therebetween or at a position enclosing the first ferromagnetic layer.

(9) The random number generator according to the aforementioned aspect may include a plurality of the random number generation unit is provided, and the voltage application unit may be shared by the plurality of the random number generation unit.

(10) An integrated device according to a second aspect includes the random number generator according to the aforementioned aspect.

The random number generator according to the aforementioned aspect can generate natural random numbers using a rotation direction difference of magnetization after a voltage is applied.

### BRIEF DESCRIPTION OF THE DRAWINGS

FIG. 1 is a schematic diagram of a random number generator according to a first embodiment.

FIG. 2 is a diagram schematically showing the operation of the random number generator.

FIG. 3 is a diagram showing a relationship between a magnetization direction of a first ferromagnetic substance in the random number generator and the duration of applied voltage pulses.

FIG. 4 is a diagram schematically showing a method of reading information from the random number generator according to the first embodiment.

FIG. 5 is a diagram schematically showing another example of the method of reading information from the random number generator according to the first embodiment.

FIG. 6 is a schematic diagram of another example of a random number generator according to the first embodiment.

FIG. 7 is a schematic diagram of another example of a random number generator according to the first embodiment.

FIG. 8 is a schematic diagram of an integrated device according to a second embodiment.

### DETAILED DESCRIPTION OF THE INVENTION

Hereinafter, embodiments of the present invention will be described in detail with reference to appropriate drawings. In the drawings used in the following description, characteristic parts may be enlarged for convenience in order to allow easy understanding of the features of the present invention, and dimensional proportions and the like of respective components may be different from the actual ones. Materials, dimensions and the like exemplified in the following description are examples and the present invention is not limited thereto and may be appropriately modified and implemented within a range in which the effects of the present invention are obtained.

### First Embodiment

### Random Number Generator

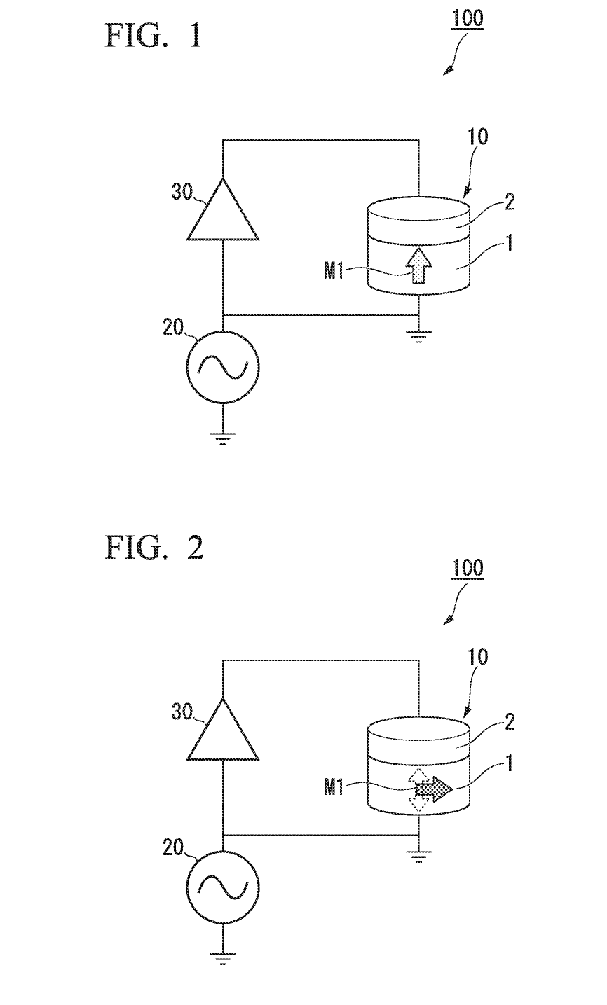

FIG. 1 is a schematic diagram of a random number generator according to a first embodiment. The random number generator 100 shown in FIG. 1 includes a random number generation unit 10, a voltage application unit 20 and a control unit 30. The voltage application unit 20 is connected in a lamination direction of the random number generation unit 10. The control unit 30 is connected to the voltage application unit 20 and controls a voltage applied to the random number generation unit 10.

### Random Number Generation Unit

The random number generation unit 10 includes a first ferromagnetic layer 1 and an insulating layer 2.

### First Ferromagnetic Layer

The first ferromagnetic layer 1 has a magnetization M1. The first ferromagnetic layer 1 has an easy magnetization direction and a hard magnetization direction, and the magnetization M1 is oriented in the easy magnetization direction in a state in which an external force is not applied. The first ferromagnetic layer 1 shown in FIG. 1 is a perpendicular magnetization film having an axis of easy magnetization in a lamination direction of the first ferromagnetic layer 1. When the perpendicular magnetization film is used, the area of the random number generation unit 10 can be reduced to decrease a device size. The first ferromagnetic layer 1 may be an in-plane magnetization film.

A known material can be used for the first ferromagnetic layer 1. For example, a metal selected from a group composed of Cr, Mn, Co, Fe and Ni and an alloy including one or more of such metals and having ferromagnetism can be used. Further, such metals and an alloy including at least one element of B, C and N can also be used. Specifically, alloys such as Co—Fe, Co—Fe13 B, Ni—Fe, Co—Ho and Sm—Fe are conceivable. Further, a Heusler alloy and the like may also be used.

### Insulating Layer

The insulating layer 2 is laminated on one side of the first ferromagnetic layer 1. The insulating layer 2 is interposed between the voltage application unit 20 and the first ferromagnetic layer 1 and thus electric fields are formed in the first ferromagnetic layer 1.

Al₂O₃, SiO₂, MgO, MgAl₂O₄ and the like can be used for the insulating layer 2. Further, in addition thereto, materials in which some of Al, Si and Mg are replaced by Zn, Be and the like can also be used.

The thickness of the insulating layer 2 is desirably equal to or greater than 2 nm, desirably equal to or greater than 5 nm or desirably equal to or greater than 10 nm. On the other hand, the thickness of the insulating layer 2 is desirably equal to or less than 20 nm or desirably equal to or less than 50 nm. When the insulating layer 2 is thin, an upper limit of a voltage which can be applied in the lamination direction of the random number generation unit 10 decreases. On the other hand, when the insulating layer 2 is thick, the insulating layer 2 emits heat and thus stability of the magnetization M1 of the first ferromagnetic layer 1 deteriorates.

### Voltage Application Unit

The voltage application unit 20 applies a voltage in the lamination direction of the first ferromagnetic layer 1 and the insulating layer 2. FIG. 1 shows the voltage application unit 20 as an AC power supply. The voltage application unit 20 is not limited to a particular device as long as it can apply a predetermined pulse voltage to the random number generation unit 10.

### Control Unit

The control unit 30 is connected to the voltage application unit 20 and controls a voltage applied by the voltage application unit 20 to the random number generation unit 10. The magnetization M1 of the first ferromagnetic layer 1 of the random number generation unit 10 performs precession using the voltage applied by the voltage application unit 20. The control unit 30 sets a voltage application time for which the voltage application unit 20 applies a voltage to the random number generation unit 10 depending on a theoretically obtained direction of the magnetization M1 during precession. For example, a switching element or the like may be used for the control unit 30.

### Operation of Random Number Generator

FIG. 2 is a diagram schematically showing the operation of the random number generator according to the first embodiment. The voltage application unit 20 applies a voltage in the lamination direction of the random number generation unit 10. When the voltage is applied in the lamination direction of the random number generation unit 10, the magnetization M1 of the first ferromagnetic layer 1 is distorted in an in-plane direction.

Subsequently, the control unit 30 stops the voltage applied to the random number generation unit 10. The magnetization M1 of the first ferromagnetic layer 1 is oriented in the direction of the axis of easy magnetization in a state in which an external force is not applied. Accordingly, the magnetization M1 of the first ferromagnetic layer 1 rotates from the in-plane direction of the first ferromagnetic layer 1 to a perpendicular direction. Here, there are a case in which the magnetization M1 rotates in the illustrated upward direction and a case in which it rotates in the downward direction. Whether the orientation of the magnetization M1 is the illustrated upward direction or the illustrated downward direction is probabilistically determined. When the magnetization M1 of the first ferromagnetic layer 1 is oriented in the in-plane direction at the time when voltage application to the random number generation unit 10 is stopped, the probability of the magnetization M1 being in the illustrated upward direction and the probability of the magnetization M1 being in the illustrated downward direction are equal and both are 50%. For example, when a case in which the magnetization M1 is in the illustrated upward direction is set to “1” and a case in which the magnetization M1 is in the illustrated downward direction is set to “0,” a random number having a 50% probability of being “1” and “0” is obtained.

Meanwhile, random numbers include a genuine random number with a generation probability of 50% and an offset random number having a deviation in one direction such as a generation probability of 60%, for example. The random number generator 100 can also output a genuine random number and an offset random number.

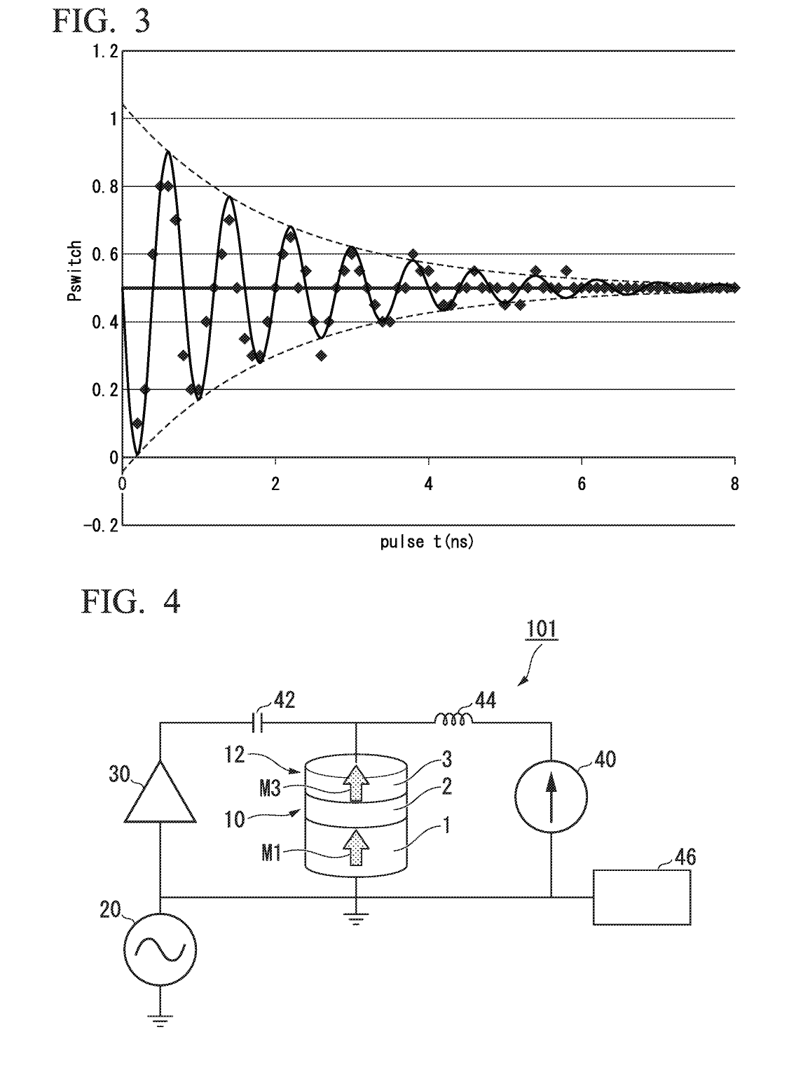

FIG. 3 is a diagram showing a relationship between the direction of the magnetization M1 of the first ferromagnetic layer 1 in the random number generator 100 and an application time of applied voltage pulses. As described above, when a voltage is applied in the lamination direction of the random number generation unit 10, the magnetization M1 of the first ferromagnetic layer 1 is distorted in the in-plane direction. The magnetization M1 of the first ferromagnetic layer 1 is distorted in the in-plane direction while performing a specific precession instead of being distorted in the in-plane direction at the moment when the voltage is applied.

In FIG. 3, the vertical axis represents a numerical value converted from an orientation direction of the magnetization M1 of the first ferromagnetic layer 1 and the horizontal axis represents a pulse width of voltage pulses applied in the lamination direction of the random number generation unit 10. The vertical axis of FIG. 3 represents a state in which the magnetization M1 of the first ferromagnetic layer 1 has been completely oriented in the in-plane direction as “0.5,” represents a state in which the magnetization M1 has been completed oriented in the illustrated upward direction as “1” and represents a state in which the magnetization M1 has been completed oriented in the illustrated downward direction as “0.”

The precession of the magnetization M1 rotates around an axis in the in-plane direction. Accordingly, the magnetization M1 oriented upward obliquely at the time when the voltage application time is 0.5 nsec is oriented downward obliquely at the time when the voltage application time is 1.0 nsec.

When voltage application is stopped at the time when the voltage application time is 0.5 nsec, it is easy for the magnetization M1 to be oriented upward and it is difficult for it to be oriented downward. The probability of the magnetization M1 being in the illustrated upward direction is about 90% and the probability of the magnetization M1 being in the illustrated downward direction is about 10%. On the other hand, when voltage application is stopped at the time when the voltage application time is 1.0 nsec, it is easy for the magnetization M1 to be oriented downward and it is difficult for it to be oriented upward. The probability of the magnetization M1 being in the illustrated upward direction is about 20% and the probability of the magnetization M1 being in the illustrated downward direction is about 80%. That is, when the control unit 30 controls the voltage application time, the random number generation unit 10 generates an offset random number having a deviation in one direction.

Meanwhile, when the voltage application time increases, the precession of the magnetization M1 converges and a magnetization rotation probability converges on 0.5.

When the magnetization rotation probability Pₛ satisfies 0.5-0.0033≤Pₛ≤0.5+0.033, the random number generator 100 generates a genuine random number. The value of ±0.0033 is a variance value (±3σ=0.0033) obtained from binomially distributed 200,000 bits which is an ideal random number and, even if the magnetization rotation probability is deviated from 0.5 to a degree of this range, it can be permitted as an error. That is, when the voltage application time is increased by the control unit 30 until the magnetization rotation probability Ps satisfies the aforementioned relationship, the random number generation unit 10 generates a genuine random number.

The graph shown in FIG. 3 can be fitted to the following equation (2).

$${P}_{S} = {A}_{0} + {A}_{1} cos ( \frac{2 π ( t - {t}_{1} )}{{τ}_{1}} ) {e}^{\frac{t - {t}_{0}}{{τ}_{0}}} \qquad ( 2 )$$

In the aforementioned equation (2), Pₛ is the magnetization rotation probability, A₀ is a value of 0.5 on which the probability converges; A₁, t₀ and t₁ are parameters obtained from a fitting curve when the random number generator 100 is measured; τ₀ is a relaxation time in which precession of the magnetization M1 of the first ferromagnetic layer 1 is disturbed by heat; and τ₁ is a time necessary for a single cycle of the precession of the magnetization M1 of the first ferromagnetic layer 1. A₁, t₀ and t₀ are values depending on the configuration of the random number generator 100 and obtained according to measurement.

When the above equation (2) is applied to conditions in which a genuine random number is generated, the following equation (3) is established.

$$0.5 - 0.0033 \leq {A}_{0} + {A}_{1} cos ( \frac{2 π ( t - {t}_{1} )}{{τ}_{1}} ) {e}^{\frac{t - {t}_{0}}{{τ}_{0}}} \leq 0.5 + 0.0033 \qquad ( 3 )$$

### Reading of Information of Random Number Generator

Subsequently, a method of outputting random numbers (a genuine random number and an offset random number) generated by the random number generation unit 10 to the outside will be described. A random number generated by the random number generation unit 10 is output as a resistance value or a voltage value. That is, the random number generator 100 is not limited to a device which outputs a random numerical value and may be a device which outputs a random resistance value and a random voltage value.

### First Reading Unit

FIG. 4 is a diagram schematically showing a method of reading information from a random number generator according to the first embodiment. A random number generator 101 shown in FIG. 4 includes a magnetoresistance effect element 12, the voltage application unit 20, the control unit 30, a DC power supply 40 and a resistance measurement unit 46. A capacitor 42 is provided between the magnetoresistance effect element 12 and the control unit 30 and a coil 44 is provided between the magnetoresistance effect element 12 and the DC power supply 40. The capacitor 42 prevents DC from flowing to the DC power supply 40 to the voltage application unit 20 and the coil 44 prevents AC from the voltage application unit 20 from flowing to the DC power supply 40.

The magnetoresistance effect element 12 includes the first ferromagnetic layer 1, the insulating layer 2 and a second ferromagnetic layer 3. The second ferromagnetic layer 3 is laminated on a surface of the insulating layer 2 opposite to the first ferromagnetic layer 1. The first ferromagnetic layer 1 and the insulating layer 2 correspond to the random number generation unit 10.

The magnetoresistance effect element 12 has a resistance value varying according to a relative angle formed between magnetizations of the first ferromagnetic layer 1 and the second ferromagnetic layer 3. When the random number generation unit 10 operates, the magnetization M1 of the first ferromagnetic layer 1 is in either of two states of parallel and anti-parallel to magnetization M3 of the second ferromagnetic layer 3. The resistance value of the magnetoresistance effect element 12 decreases when the magnetization M1 of the first ferromagnetic layer 1 is parallel to the magnetization M3 of the second ferromagnetic layer 3 and increases when the magnetization M1 of the first ferromagnetic layer 1 is anti-parallel to the magnetization M3 of the second ferromagnetic layer 3.

When current is applied from the DC power supply 40 in the lamination direction of the magnetoresistance effect element 12, the resistance value of the magnetoresistance effect element 12 can be measured by the resistance measurement unit 46. When the random number generation unit 10 is operated multiple times, a state in which the magnetization M1 of the first ferromagnetic layer 1 is parallel to the magnetization M3 of the second ferromagnetic layer 3 and a state in which the magnetization M1 of the first ferromagnetic layer 1 is anti-parallel to the magnetization M3 of the second ferromagnetic layer 3 randomly occur. The resistance measurement unit 46 outputs such a state difference as a resistance value and outputs a random number generated in the random number generation unit 10.

The second ferromagnetic layer 3 is a fixed layer having stronger magnetic anisotropy than the first ferromagnetic layer 1 and a magnetization direction fixed to one direction. The same material as that for the first ferromagnetic layer 1 can be used for the second ferromagnetic layer 3. To further increase the coercivity of the second ferromagnetic layer 3, an antiferromagnetic material such as IrMn and PtMn may come into contact with the surface of the second ferromagnetic layer 3 opposite the insulating layer 2. Further, in order to prevent a leakage magnetic field of the second ferromagnetic layer 3 from affecting the first ferromagnetic layer 1, the second ferromagnetic layer may have a synthetic ferromagnetic coupling structure.

### Second Reading Unit

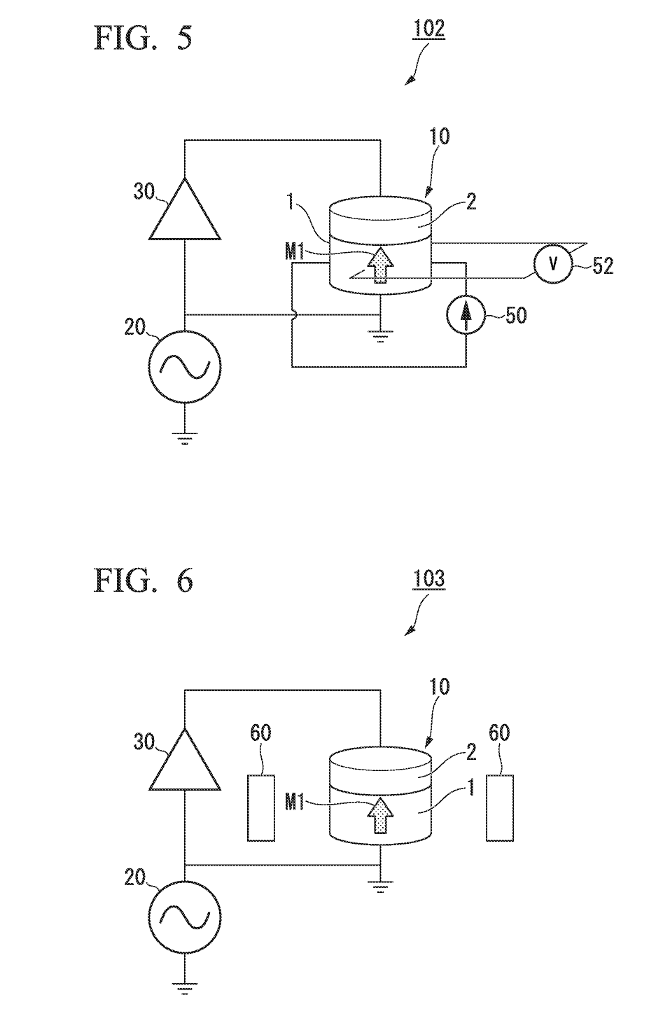

FIG. 5 is a diagram schematically showing another example of the method of reading information from a random number generator according to the first embodiment. A random number generator 102 shown in FIG. 5 includes the random number generation unit 10, the voltage application unit 20, the control unit 30, a current application unit 50 and a voltmeter 52.

When current flows in a first direction of the in-plane direction of the first ferromagnetic layer 1 according to the current application unit 50, a potential difference is generated in a second direction perpendicular to the first direction according to anomalous Hall effect. The potential different caused by the anomalous Hall effect varies with the direction of the magnetization M1 of the first ferromagnetic layer 1.

A potential difference variation associated with the anomalous Hall effect is measured by the voltmeter 52. When the random number generation unit 10 is operated multiple times, the magnetization M1 of the first ferromagnetic layer 1 is oriented in any of the illustrated upward direction and the illustrated downward direction. The voltmeter 52 outputs this state difference as a voltage value and outputs a random number generated in the random number generation unit 10.

As described above, the random number generators 100, 101 and 102 according to the present embodiment can generate a genuine random number or an offset random number by controlling a voltage application time of the voltage application unit 20 through the control unit 30. In addition, the random number generation unit 10 is driven with a voltage and thus can reduce power consumption. Further, if a genuine random umber is generated, it is desirable to apply a voltage for a sufficient period of time and precise control is not necessary.

The present invention is not limited to the above-described embodiment and may be modified in various manners without departing from the scope of the present invention.

For example, FIG. 6 is a schematic diagram of another example of a random number generator according to the first embodiment. The random number generator 103 shown in FIG. 6 differs from the random number generator 100 shown in FIG. 1 in that the random number generator 103 has a magnetic field application unit 60. Other components are the same as those of the random number generator 100 and thus a description thereof is omitted.

The magnetic field application unit 60 is disposed at a position at which the magnetic field application unit 60 can apply an external magnetic field to the first ferromagnetic layer 1. The magnetic field application unit 60 applies a magnetic field in a direction perpendicular to the axis of easy magnetization of the first ferromagnetic layer 1. When the voltage application unit 20 applies a voltage to the first ferromagnetic layer 1, the magnetization M1 of the first ferromagnetic layer 1 is oriented in the in-plane direction while performing precession. To cause the magnetization M1 oriented in the direction of the axis of easy magnetization to perform precession, a certain energy level or higher is required. It is possible to advance start of precession by applying an external magnetic field through the magnetic field application unit 60.

On the other hand, after the magnetization M1 starts precession, precession of the magnetization M1 is stabilized when an external magnetic field is not applied. Accordingly, it is desirable that the magnetic field application unit 60 be able to modulate a magnetic field to be applied. In addition, the intensity of a magnetic field to be applied may be modulated according to a precession period.

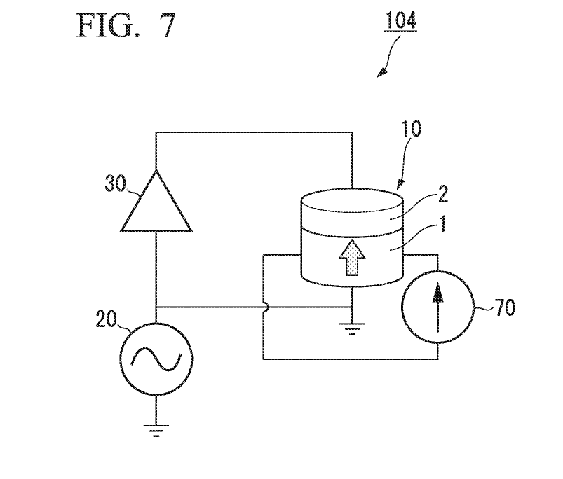

Furthermore, FIG. 7 is a schematic diagram of another example of a random number generator according to the first embodiment, for example. The random number generator 104 shown in FIG. 7 differs from the random number generator 100 shown in FIG. 1 in that the random number generator 104 has a second voltage application unit 70. Other components are the same as those of the random number generator 100 and thus a description thereof is omitted.

The second voltage application unit 70 is connected in the in-plane direction of the first ferromagnetic layer 1. The second voltage application unit 70 applies a voltage in the in-plane direction of the first ferromagnetic layer 1. The magnetization M1 of the first ferromagnetic layer 1 is easily oriented in a perpendicular direction by being affected by the interface between the first ferromagnetic layer 1 and the insulating layer 2. When a voltage is applied in the in-plane direction of the first ferromagnetic layer 1, the influence of the interface can be weakened and thus the magnetization M1 of the first ferromagnetic layer 1 is easily distorted in the in-plane direction. That is, it is possible to advance start of precession of the magnetization M1 by applying a voltage in the in-plane direction of the first ferromagnetic layer 1 through the second voltage application unit 70.

In addition, to suppress the influence of interfaces from peripheral circuits, a magnetic shield may be provided at positions which the first ferromagnetic layer is interposed therebetween or at a position enclosing the first ferromagnetic layer 1. This can prevent fluctuation in random numbers associated with external factors.

The magnetic field application unit 60, the second voltage application unit 70 and the magnetic shield may be used alone or may be combined to be used.

### Second Embodiment

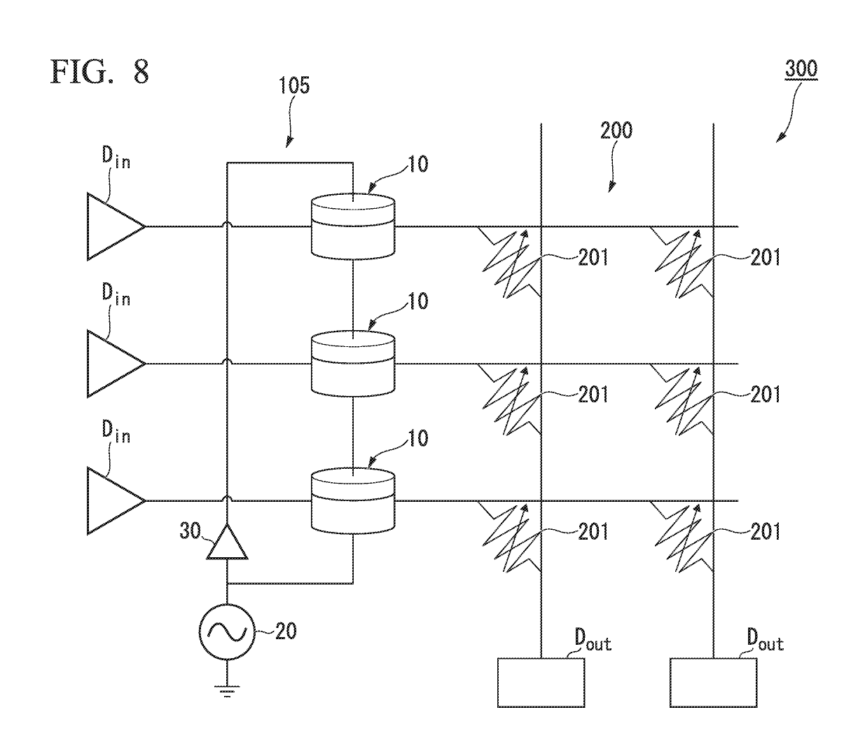

An integrated device according to the second embodiment includes the random number generator according to the first embodiment. FIG. 8 is a schematic diagram of an example of the integrated device according to the second embodiment.

The integrated device 300 shown in FIG. 8 includes a plurality of input units Dᵢₙ, a random number generator 105, a product-sum operation unit 200, and a plurality of output units Dₒᵤₜ. The integrated device 300 may be used as a neuromorphic device (NMD) which realizes a neural network which models a nerve system using a resistance variable element array. The NMD weights information and transfers the weighted information from a previous stage to the next state. A nerve system is modeled by weighting information.

The random number generator 105 includes a plurality of the random number generation units 10, the voltage application unit 20 and the control unit 30. The voltage application unit 20 is shared by the plurality of the random number generation units 10.

The product-sum operation unit 200 includes a plurality of resistance variable elements 201. The product-sum operation unit 200 combines a plurality of resistance variable elements 201 having continuously varying resistance and performs multiplication on input signals input from the input units Dᵢₙ using each resistance value as a weight. In addition, the product-sum operation unit 200 performs a sum operation by obtaining the sum of the current output therefrom.

In the NMD, in a case in which information is weighted and transferred from a previous stage to the next stage, there are cases in which a weight is randomly applied, and cases in which a set weight is applied. The random number generator 105 applies a random weight and the product-sum operation unit 200 applies a set weight. That is, the integrated device 300 can apply weights to input signals input from the input units Dᵢₙ and output the signals through the output units Dₒᵤₜ.

Here, although the NMD is presented as an example of the integrated device, the integrated device is not limited to this case. For example, a random number generator may be connected to a semiconductor circuit such as a transistor, and the like and may be used as a semiconductor integrated device. In addition, the integrated device may be used as a random number generator such as a quantum computer code generator, an authentication system or a stochastic computer which performs operations using probability.

### EMBODIMENTS

### Embodiment 1

MgO (10 nm)/Cr (10 nm)/Au (50 nm)/Fe₈₀Co₂₀ (0.7 nm)/MgO (1.5 nm)/Fe (10 nm)/Au (5 nm) are formed on an (001)-oriented MgO substrate using MBE film formation method and an upper electrode is patterned thereon to form a device. The planar shape of the device is an oval having a short axis of 200 nm and a long axis of 800 nm. In addition, a control unit and a voltage source are connected to the upper electrode and a lower electrode of the device to manufacture a random number generator.

Subsequently, a voltage is applied to the device while varying a voltage application time t, and magnetization rotation probability at each time the voltage application time t is varied is measured. An external applied magnetic field Hₑₓₜ of 700 Oe and an applied pulse voltage of −1.0 V/nm⁻¹ are used as measurement conditions. The measurement result corresponds to FIG. 3.

Variation in the magnetization rotation probability P of the first ferromagnetic layer with respect to the voltage application time t is affected by a time τ₁ required for one period associated with precession of magnetization M, and a relaxation time τ₀ in which precession of the magnetization M is disturbed by heat and represented as Equation (2).

Parameters can be obtained from the measurement values shown in FIG. 3 as A₀ =0.5, A₁=0.6, t₀=−0.2 nsec, t₁=−0.2 nsec, τ₀=2 nsec and τ₁=0.8 nsec. The magnetization rotation probability Pₛ converges within 0.5±0.0022 from the data fitting result and thus the random number generator in embodiment 1 can generate a genuine random number by applying a voltage pulse of 11 nsec or more.

The random number generator according to the above-described embodiment can generate a natural random number using a magnetization rotation direction difference after a voltage is applied.

### EXPLANATION OF REFERENCES

1 First ferromagnetic layer

2 Insulating layer

3 Second ferromagnetic layer

10 Random number generation unit

12 Magnetoresistance effect element

20 Voltage application unit

30 Control unit

40 DC power supply

42 Capacitor

44 Coil

46 Resistance measurement unit

50 Current application unit

52 Voltmeter

60 Magnetic field application unit

70 Second voltage application unit

100, 101, 102, 103, 104, 105 Random number generator

200 Product-sum operation unit

300 Integrated device

M1, M3 Magnetization

Dᵢₙ Input unit

Dₒᵤₜ Output unit

What is claimed is:

1. A random number generator comprising:
a random number generation unit having a first ferromagnetic layer and a nonmagnetic insulating layer laminated on one surface of the first ferromagnetic layer;
a voltage application unit which is connected in the lamination direction of the first ferromagnetic layer and the insulating layer and is configured to apply a voltage in the lamination direction of the first ferromagnetic layer and the insulating layer; and
a control unit which is connected to the voltage application unit and is configured to determine a time for which a voltage is applied to the first ferromagnetic layer depending on a direction of magnetization of the first ferromagnetic layer precessing by applying the voltage.

2. The random number generator according to claim 1, wherein the control unit is configured to control a voltage application time t such that the voltage application time satisfies the following equation (1),
$$0.5 - 0.0033 \leq {A}_{0} + {A}_{1} cos ( \frac{2 π ( t - {t}_{1} )}{{τ}_{1}} ) {e}^{\frac{t - {t}_{0}}{{τ}_{0}}} \leq 0.5 + 0.0033 \qquad ( 1 )$$
wherein, in equation (1), A₀ is a value of 0.5; A₁, t₀ and t₁ are parameters obtained from a fitting curve when the random number generator is measured; τ₀ is a relaxation time in which precession of the magnetization of the first ferromagnetic layer is disturbed by heat; and τ₁ is a time necessary for a single cycle of the precession of the magnetization of the first ferromagnetic layer.

3. The random number generator according to claim 1, wherein the thickness of the insulating layer is 2 nm or more.

4. The random number generator according to claim 2, wherein the thickness of the insulating layer is 2 nm or more.

5. The random number generator according to claim 1, further comprising a magnetic field application unit which is disposed at a position at which the magnetic field application unit is able to apply an external magnetic field to the first ferromagnetic layer and is configured to apply a magnetic field in a direction perpendicular to an axis of easy magnetization of the first ferromagnetic layer.

6. The random number generator according to claim 2, further comprising a magnetic field application unit which is disposed at a position at which the magnetic field application unit is able to apply an external magnetic field to the first ferromagnetic layer and is configured to apply a magnetic field in a direction perpendicular to an axis of easy magnetization of the first ferromagnetic layer.

7. The random number generator according to claim 3, further comprising a magnetic field application unit which is disposed at a position at which the magnetic field application unit is able to apply an external magnetic field to the first ferromagnetic layer and is configured to apply a magnetic field in a direction perpendicular to an axis of easy magnetization of the first ferromagnetic layer.

8. The random number generator according to claim 4, further comprising a magnetic field application unit which is disposed at a position at which the magnetic field application unit is able to apply an external magnetic field to the first ferromagnetic layer and is configured to apply a magnetic field in a direction perpendicular to an axis of easy magnetization of the first ferromagnetic layer.

9. The random number generator according to claim 1, further comprising a second voltage application unit which is connected in an in-plane direction of the first ferromagnetic layer and is configured to apply a voltage in the in-plane direction of the first ferromagnetic layer.

10. The random number generator according to claim 1, further comprising a second ferromagnetic layer provided on a surface of the insulating layer opposite to the first ferromagnetic layer.

11. The random number generator according to claim 1, further comprising:
a current application unit which is connected in the in-plane direction of the first ferromagnetic layer and is configured to flow current in a first direction of the in-plane direction of the first ferromagnetic layer; and
a voltmeter which is configured to measure a potential difference in a second direction perpendicular to the first direction.

12. The random number generator according to claim 1, further comprising a magnetic shield provided at positions which the first ferromagnetic layer is interposed therebetween or at a position enclosing the first ferromagnetic layer.

13. The random number generator according to claim 1, wherein a plurality of the random number generation unit is provided, and
the voltage application unit is shared by the plurality of the random number generation unit.

14. An integrated device comprising the random number generator according to claim 1.
